(19) United States
(12) Patent Application Publication
(10) Pub. No.: US 2014/0166099 A1
(43) Pub. Date: Jun. 19, 2014

(54) CRYSTALLINE PHOTOVOLTAIC CELLS AND METHODS OF MANUFACTURING

(71) Applicant: SunEdison, Inc., St. Peters, MO (US)

(72) Inventors: Hongbin Fang, San Jose, CA (US); Bo Li, Sunnyvale, CA (US); Hsiu-Wu Guo, Seattle, WA (US); Bang Nguyen, Palo Alto, CA (US)

(21) Appl. No.: 14/098,918

(22) Filed: Dec. 6, 2013

Related U.S. Application Data
(60) Provisional application No. 61/737,589, filed on Dec. 14, 2012.

(51) Int. Cl. H01L 31/0224; H01L 31/05; H01L 31/18

(52) U.S. Cl. CPC H01L 31/022425; H01L 31/18; H01L 31/0508
USPC 136/256; 438/98

(57) ABSTRACT

Crystalline photovoltaic (PV) cells and methods of manufacturing cells are described. One example method of manufacturing a PV cell includes depositing a plurality of first fingers on a crystalline silicon wafer. The first fingers extend in a first direction parallel to each other and comprise a substantially non-silver conductive material.

### CROSS-REFERENCE TO RELATED APPLICATIONS

This application claims priority to U.S. Provisional Application No. 61/737,589 filed Dec. 14, 2012, the entire disclosure of which is hereby incorporated by reference in its entirety.

### FIELD

This disclosure generally relates to photovoltaic (PV) cells and methods of manufacturing PV cells and, more specifically, to crystalline PV cells with electrodes and methods of manufacturing the same.

### BACKGROUND

Photovoltaic (PV) modules are devices which convert solar energy into electricity. A PV module typically includes several PV cells (connected in series and/or in parallel) that generate electricity in response to sunlight incident on the surface of the cells.

To extract energy from the PV cells, electrodes are manufactured on one or both faces of a crystalline silicon wafer. Various techniques are known for manufacturing PV cell electrodes. In one known method, electrodes include fingers and bus bars are screen printed onto a surface of the silicon wafer using silver (Ag) paste. Some other PV cells are manufactured by screen printing fingers from silver and soldering separate bus bars to fingers. In still another technique, fingers are screen printed on the silicon wafer using silver. A copper (Cu) mesh electrode is positioned over the screen printed fingers. The mesh electrode includes thin (relative to bus bars) copper fingers that extend parallel to each other and intercept the silver screen printed fingers. The copper fingers are electrically coupled to the screen printed fingers and serve the same purpose as bus bars. Some of the known techniques are electrically inefficient (e.g., exhibit unacceptably high ohmic losses), manpower inefficient, use costly material (e.g. silver), and/or are otherwise relatively costly.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a method of manufacturing a photovoltaic (PV) cell. The method includes depositing a plurality of first fingers on a crystalline silicon wafer. The first fingers extend in a first direction parallel to each other and comprise a substantially non-silver conductive material.

Another aspect of the present disclosure is photovoltaic (PV) cell. The PV cell includes a crystalline silicon substrate, and a plurality of first fingers disposed on the crystalline silicon wafer. The first fingers extend in a first direction parallel to each other and comprise a substantially non-silver conductive material.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of an example solar module

FIG. 2 is a cross-sectional view of the solar module shown in FIG. 1 taken along the line A-A;

FIG. 3 is a top plan view of an example silicon wafer including a PV cell for use in the solar module shown in FIG. 1;

FIG. 4 is a top plan view of an example PV cell;

FIG. 5 is a top plan view of the PV cell shown in FIG. 4 during manufacture of the cell; and

FIG. 6 is a top plan view of a copper mesh for use with the PV cell shown in FIG. 5.

Like reference symbols in the various drawings indicate like elements.

### DETAILED DESCRIPTION

The embodiments described herein generally relate to photovoltaic (PV) cells and methods of manufacturing PV cells. More specifically, embodiments described herein relate to crystalline PV cells with non-silver electrodes and methods of manufacturing the same

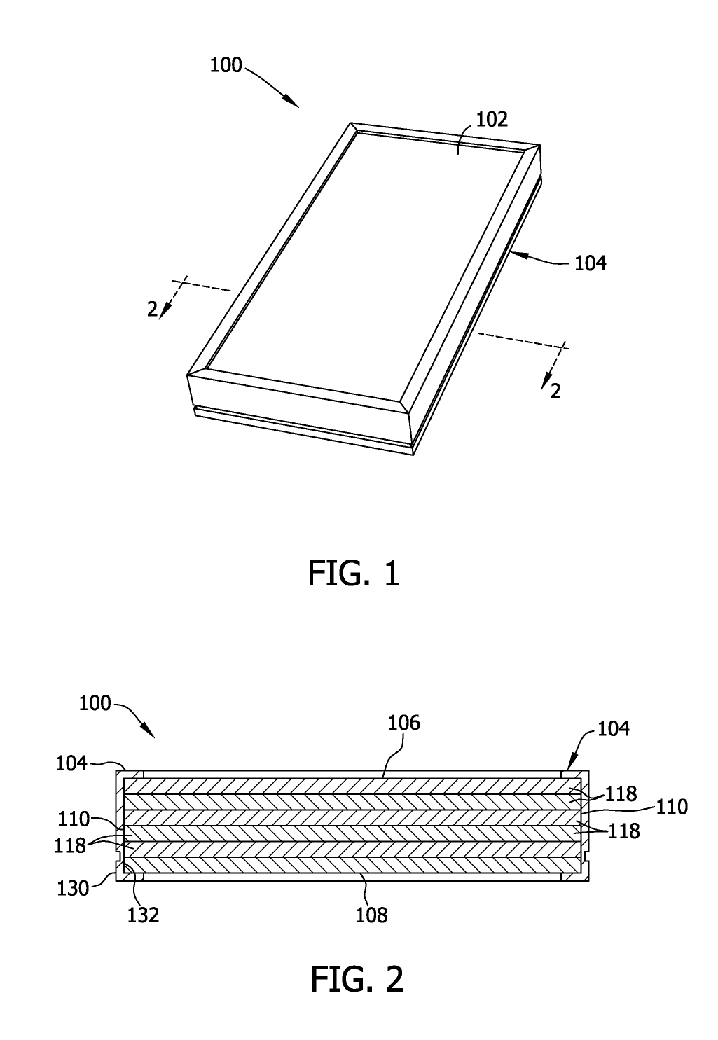

Referring initially to FIGS. 1 and 2, a solar module of one embodiment is indicated generally at 100. A perspective view of solar module 100 is shown in FIG. 1. FIG. 2 is a cross sectional view of solar module 100 taken at line A-A shown in FIG. 1. Solar module 100 includes a solar panel 102 and a frame 104 circumscribing solar panel 102.

Solar panel 102 includes a top surface 106 and a bottom surface 108 (shown in FIG. 2). Edges 110 extend between top surface 106 and bottom surface 108. In this embodiment, solar panel 102 is rectangular shaped. In other embodiments, solar panel 102 may have any suitable shape.

As shown in FIG. 2, the solar panel 102 has a laminate structure that includes several layers 118. Layers 118 may include for example glass layers, non-reflective layers, electrical connection layers, n-type silicon layers, p-type silicon layers, and/or backing layers. In other embodiments, solar panel 102 may have more or fewer, including one, layers 118, may have different layers 118, and/or may have different types of layers 118.

As shown in FIG. 1, frame 104 circumscribes solar panel 102. Frame 104 is coupled to solar panel 102, as best shown in FIG. 2. Frame 104 assists in protecting edges 110 of solar panel 102. Exemplary frame 104 includes an outer surface 130 spaced apart from solar panel 102 and an inner surface 132 adjacent solar panel 102. Outer surface 130 is spaced apart from and substantially parallel to inner surface 132. In the exemplary embodiment, frame 104 is made of aluminum. More particularly, in some embodiments frame 104 is made of 6000 series anodized aluminum. In other embodiments, frame 104 may be made of any other suitable material providing sufficient rigidity including, for example, rolled or stamped stainless steel, plastic or carbon fiber.

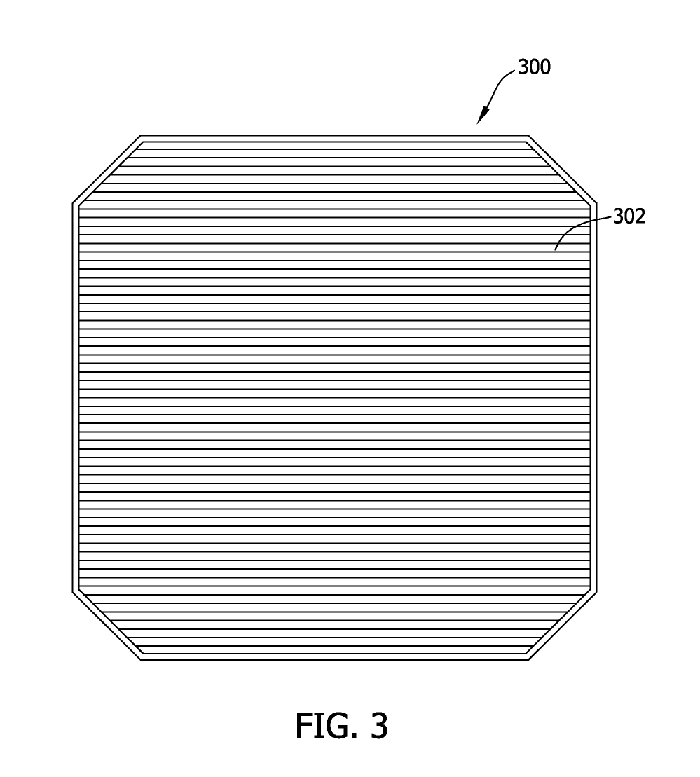

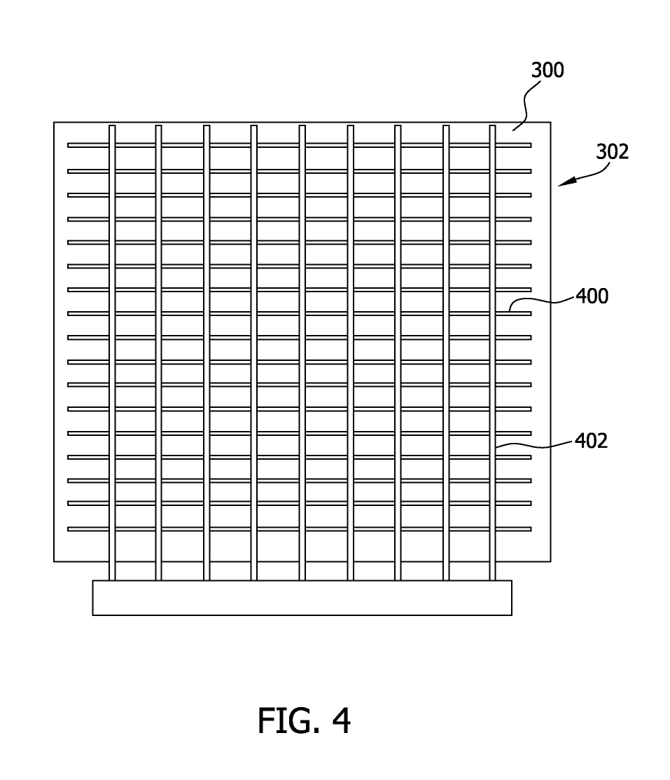

At least one layer 118 of solar panel 102 includes photovoltaic (PV) cells. PV cells are constructed from crystalline silicon wafers. FIG. 3 is an illustration of a pseudo-square silicon wafer 300 with a PV cell 302 partially manufactured thereon. FIG. 4 is an example of a completed PV cell 302 fabricated on a square silicon wafer 300. PV cell 302 may be a front diffused emitter or a heterojunction PV cell. In other embodiments, PV cell may be any other suitable type of PV cell.

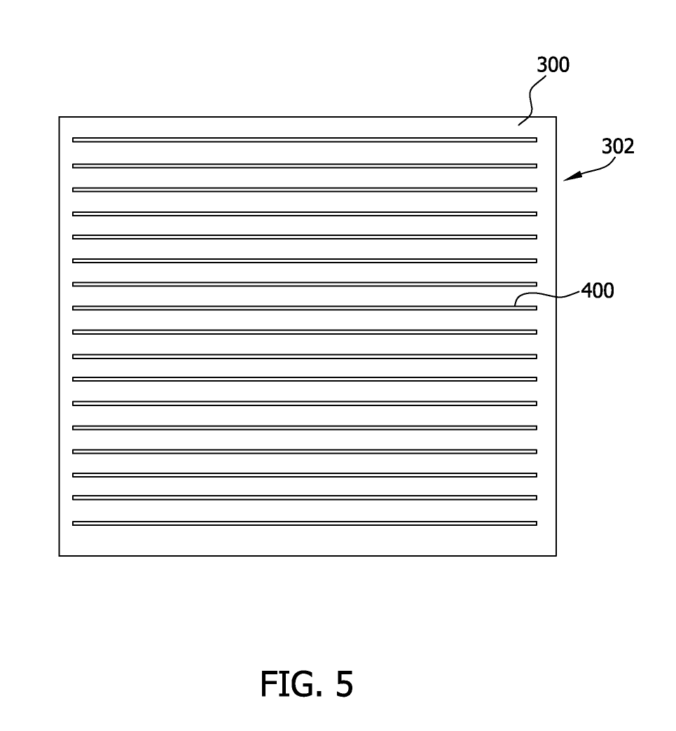

During the manufacture of PV cells 302, electrodes are manufactured on silicon wafer 300 in the areas that will form PV cell 302. In this embodiment, the electrodes include first fingers 400 manufactured on wafer 300 and second fingers 402 applied to wafer 300 and coupled to the first fingers 400. FIG. 5 is an illustration of a PV cell 302 during manufacture. First fingers 400 have been manufactured on the surface of the wafer 300. First fingers 400 are electrically conductive fingers connected to and extending in parallel across the surface of wafer 300. First fingers 400 conduct electricity generated by PV cell 302. In the exemplary embodiment, first fingers 400 are copper (Cu) fingers. In other embodiments, first fingers 400 may be made from any other suitably conductive metal, alloy, and/or nonmetallic material including, for example aluminum, nickel, tin, and/or titanium. In some embodiments, first fingers 400 are made from any electrically conductive, relatively low resistance, and relatively inexpensive material. Fingers 400 are suitably made from a material that includes no silver (Ag) or is substantially silver free.

In this embodiment, first fingers 400 are applied to wafer 300 by screen printing. Screen printing is well known to those skilled in the art and will not be described in detail. In general, a copper paste is applied to wafer 300 through a mask (not shown) that allows the paste to pass to the wafer only in the locations desired for forming the first fingers 400. Wafer 400 is then heated to remove solvents and binders used in the paste, leaving behind the copper first fingers 400. In other embodiments, any other suitable method for forming first fingers 400 may be used. For example, in some embodiments first fingers 400 are formed on PV cell 302 using electroless plating and/or electrochemical plating techniques. In still other embodiments, plasma vapor deposition (PVD), by sputtering or evaporation, may be used to manufacture first fingers 400 on wafer 300.

Rather than using two or three discrete bus bars to couple to first fingers 400, a greater number of smaller, more closely spaced second fingers 402 are coupled to wafer 300 to carry current from first fingers 400. Any suitable number of second fingers 400 may be used. In some embodiments PV cell 302 includes four or more second fingers 400.

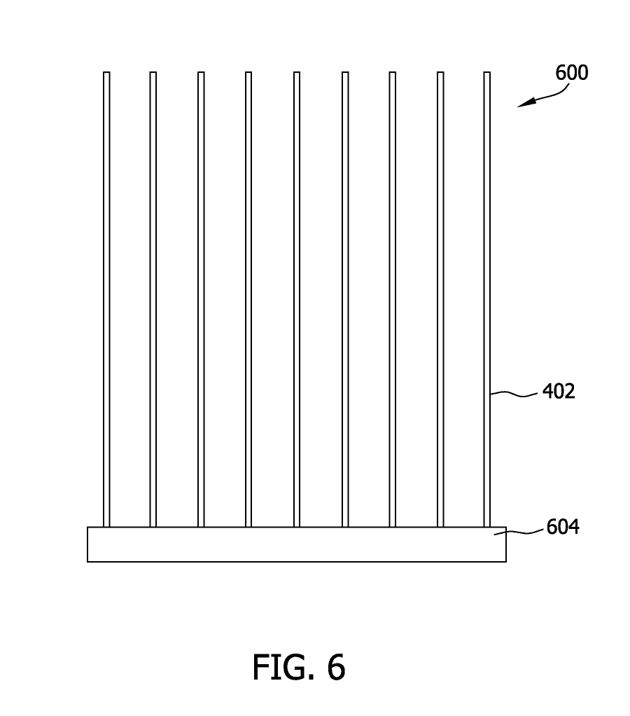

One exemplary type of second fingers 402 is shown in FIG. 6. FIG. 6 is a mesh 600 including second fingers 402 for placement on wafer 300. Mesh 600 includes second fingers 402 coupled to a terminal 604. In this embodiment, mesh 600 is made of copper. In other embodiments, mesh 600 is made of any other suitable conductive material. Second fingers 402 are copper finger cores with an alloy coating (e.g., a solder coating). Mesh 600 is disposed over PV cell 302. Pressure and heat are applied to soften the alloy coating, allowing the copper finger cores to contact first fingers 400 and allowing the alloy coating to bond to the surface of wafer 300. The application of copper mesh to a form a PV cell is well known to those of ordinary skill in the art and will not be further described herein.

In the illustrated embodiment, copper mesh 600 includes nine of the second fingers 402. In other embodiments, mesh 600 may include more or fewer second fingers 402. In some embodiments, mesh 600 includes more than four second fingers 402. In contrast, a similar PV cell constructed using discrete bus bars attached to first fingers 400 commonly includes only two or three discrete bus bars. Such bus bars are spaced significantly farther apart than second fingers 402 and are significantly wider than second fingers 402. In some known 156 millimeter (mm) PV cells, bus bars are spaced about 78 mm or 52 mm apart. In contrast, second fingers 402 are spaced as close as 8 mm apart. Thus, the effective length of first fingers 400 is reduced in the exemplary PV cell 302 to about 8 mm as compared to 52 mm or 78 mm in some known PV cells.

In other embodiments, mesh 600 is not used and second fingers 402 are formed using several (e.g., four or more) thin, electrically conductive wires. The wires are disposed on wafer 300 in a similar arrangement to second fingers 402 shown in FIG. 4. The wires are mechanically coupled to wafer 300 and electrically coupled to first fingers 400, for example by soldering. The conductive wires may be made from any suitable electrically conductive material including, for example, silver, copper, tin, etc.

The PV cells and methods described achieve superior results to some known methods. The PV cells may be manufactured more easily and efficiently than these known methods. Moreover, the material cost of the PV cells may be reduced by, for example, the use of copper and other inexpensive metals for fabrication of the fingers of the PV cell rather than the commonly used, and more expensive, silver.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A method of manufacturing a photovoltaic (PV) cell, the method comprising:
depositing a plurality of first fingers on a crystalline silicon wafer, the first fingers extending in a first direction parallel to each other, the first fingers comprising a substantially non-silver conductive material.

2. The method according to claim 1, wherein the substantially non-silver conductive material comprises copper.

3. The method according to claim 1, wherein the substantially non-silver conductive material comprises aluminum.

4. The method according to claim 1, wherein the substantially non-silver conductive material comprises nickel.

5. The method according to claim 1, wherein the substantially non-silver conductive material comprises titanium.

6. The method according to claim 1, wherein the substantially non-silver conductive material comprises tin.

7. The method according to claim 1, wherein the substantially non-silver conductive material comprises a plurality of metals.

8. The method according to claim 1, wherein depositing a plurality of first fingers on a crystalline silicon wafer comprises electroless plating a plurality of first fingers on a crystalline silicon wafer.

9. The method according to claim 1, wherein depositing a plurality of first fingers on a crystalline silicon wafer comprises electrochemically plating a plurality of first fingers on a crystalline silicon wafer.

10. The method according to claim 1, wherein depositing a plurality of first fingers on a crystalline silicon wafer comprises depositing a plurality of first fingers on a crystalline silicon wafer using plasma vapor deposition.

11. The method according to claim 1, wherein depositing a plurality of first fingers on a crystalline silicon wafer comprises screen printing a plurality of first fingers on a crystalline silicon wafer.

12. The method according to claim 1, further comprising disposing a copper mesh on the silicon wafer, the copper mesh including a plurality of second fingers, the copper mesh disposed on the silicon wafer with the second fingers extending in a second direction that intercepts the first fingers.

13. The method according to claim 12, wherein the plurality of second fingers comprises four or more second fingers.

14. A photovoltaic (PV) cell comprising:
a crystalline silicon substrate; and
a plurality of first fingers disposed on the crystalline silicon wafer, the first fingers extending in a first direction parallel to each other, the first fingers comprising a substantially non-silver conductive material.

15. The PV cell according to claim 14, wherein the substantially non-silver conductive material comprises aluminum.

16. The PV cell according to claim 14, wherein the substantially non-silver conductive material comprises nickel.

17. The PV cell according to claim 14, wherein the substantially non-silver conductive material comprises titanium.

18. The PV cell according to claim 14, wherein the substantially non-silver conductive material comprises a plurality of metals.

19. The PV cell according to claim 14, wherein the substantially non-silver conductive material comprises tin.

20. The PV cell according to claim 14, wherein the substantially non-silver conductive material comprises copper.

21. The PV cell according to claim 14, wherein the plurality of first fingers are electrically coupled to the crystalline silicon substrate.

22. The PV cell according to claim 14, further comprising a copper mesh disposed on the crystalline silicon wafer, the copper mesh including a plurality of second fingers, the copper mesh disposed on the silicon wafer with the second fingers extending in a second direction intercepting the first direction and the second fingers overlying and electrically coupled to the first fingers.

23. The PV cell according to claim 22, wherein the plurality of second fingers comprises four or more second fingers.

24. The PV cell according to claim 22, wherein the copper mesh further comprises a terminal electrically coupled to the plurality of second fingers.
